(19) United States
(12) Patent Application Publication
(10) Pub. No.: US 2016/0254318 A1
(43) Pub. Date: Sep. 1, 2016

(54) MAGNETIC RANDOM ACCESS MEMORY (MRAM) BIT CELLS EMPLOYING SOURCE LINES (SLs) AND/OR BIT LINES (BLs) DISPOSED IN MULTIPLE, STACKED METAL LAYERS TO REDUCE MRAM BIT CELL RESISTANCE

(71) Applicant: QUALCOMM Incorporated, San Diego, CA (US)

(72) Inventors: Yu Lu, San Diego, CA (US); Xiaochun Zhu, San Diego, CA (US); Seung Hyuk Kang, San Diego, CA (US)

(21) Appl. No.: 14/856,316

(22) Filed: Sep. 16, 2015

Related U.S. Application Data
(60) Provisional application No. 62/121,982, filed on Feb. 27, 2015.

(51) Int. Cl. H01L 27/22; H01L 43/12; H01L 43/08; G11C 11/16; H01L 43/02

(52) U.S. Cl. CPC H01L 27/222; G11C 11/161; H01L 43/02; H01L 43/08; H01L 43/12

(57) ABSTRACT

Magnetic random access memory (MRAM) bit cells employing source lines and/or bit lines disposed in multiple, stacked metal layers to reduce MRAM bit cell resistance are disclosed. Related methods and systems are also disclosed. In aspects disclosed herein, MRAM bit cells are provided in a memory array. The MRAM bit cells are fabricated in an integrated circuit (IC) with source lines and/or bit lines formed by multiple, stacked metal layers disposed above a semiconductor layer to reduce the resistance of the source lines. In this manner, if node size in the IC is scaled down, the resistance of the source lines and/or the bit lines can be maintained or reduced to avoid an increase in drive voltage that generates a write current for write operations for the MRAM bit cells.

### PRIORITY APPLICATION

The present application claims priority under 35 U.S.C. §119(e) to U.S. Provisional Patent Application Ser. No. 62/121,982 filed on Feb. 27, 2015 and entitled “MAGNETIC RANDOM ACCESS MEMORY (MRAM) BIT CELLS EMPLOYING SOURCE LINES (SLs) AND/OR BIT LINES (BLs) DISPOSED IN MULTIPLE, STACKED METAL LAYERS TO REDUCE MRAM BIT CELL RESISTANCE,” which is incorporated herein by reference in its entirety.

### BACKGROUND

I. Field of the Disclosure

The technology of the disclosure relates generally to magnetic tunnel junctions (MTJs), and more particularly to MTJs employed in magnetic random access memory (MRAM) bit cells to provide MRAM.

II. Background

Semiconductor storage devices are used in integrated circuits (ICs) in electronic devices to provide data storage. One example of a semiconductor storage device is magnetic random access memory (MRAM). MRAM is non-volatile memory in which data is stored by programming a magnetic tunnel junction (MTJ) as part of an MRAM bit cell. One advantage of an MRAM is that MTJs in MRAM bit cells can retain stored information even when power is turned off. This is because data is stored in the MTJ as a small magnetic element rather than as an electric charge or current.

In this regard, an MTJ comprises a free ferromagnetic layer (“free layer”) disposed above or below a fixed or pinned ferromagnetic layer (“pinned layer”). The free and pinned layers are separated by a tunnel junction or barrier formed by a thin non-magnetic dielectric layer. The magnetic orientation of the free layer can be changed, but the magnetic orientation of the pinned layer remains fixed or “pinned.” Data can be stored in the MTJ according to the magnetic orientation between the free and pinned layers. When the magnetic orientations of the free and pinned layers are anti-parallel (AP) to each other, a first memory state exists (e.g., a logical ‘1’). When the magnetic orientations of the free and pinned layers are parallel (P) to each other, a second memory state exists (e.g., a logical ‘0’). The magnetic orientations of the free and pinned layers can be sensed to read data stored in the MTJ by sensing a resistance when current flows through the MTJ. Data can also be written and stored in the MTJ by applying a magnetic field to change the orientation of the free layer to either a P or AP magnetic orientation with respect to the pinned layer.

Recent developments in MTJ devices involve spin torque transfer (STT)-MRAM devices. In STT-MRAM devices, the spin polarization of carrier electrons, rather than a pulse of a magnetic field, is used to program the state stored in the MTJ (i.e., a ‘0’ or a ‘1’). FIG. 1 illustrates a STT-MTJ 100. The STT-MTJ 100 is provided as part of an MRAM bit cell 102 to store non-volatile data. A metal-oxide semiconductor (typically n-type MOS, i.e., NMOS) access transistor 104 is provided to control reading and writing to the STT-MTJ 100. A drain (D) of the access transistor 104 is coupled to a bottom electrode 106 of the STT-MTJ 100, which is coupled to a pinned layer 108 for example. A word line (WL) is coupled to a gate (G) of the access transistor 104. A source (S) of the access transistor 104 is coupled to a voltage source (Vs) through a source line (SL). The voltage source (V_{S}) provides a voltage (V_{SL}) on the source line (SL). A bit line (BL) is coupled to a top electrode 110 of the STT-MTJ 100, which is coupled to a free layer 112 for example. The pinned layer 108 and the free layer 112 are separated by a tunnel barrier 114.

With continuing reference to FIG. 1, when writing data to the STT-MTJ 100, the gate (G) of the access transistor 104 is activated by activating the word line (WL). A voltage differential between a voltage (V_{BL}) on the bit line (BL) and the voltage (V_{SL}) on the source line (SL) is applied. As a result, a write current (I) is generated between the drain (D) and the source (S) of the access transistor 104. If the magnetic orientation of the STT-MTJ 100 in FIG. 1 is to be changed from AP to P, a write current (I_{AP-P}) flowing from the free layer 112 to the pinned layer 108 is generated. This induces a spin transfer torque (STT) at the free layer 112 to change the magnetic orientation of the free layer 112 to P with respect to the pinned layer 108. If the magnetic orientation is to be changed from P to AP, a current (I_{P-AP) flowing from the pinned layer 108 to the free layer 112 is produced, which induces an STT at the free layer 112 to change the magnetic orientation of the free layer 112 to AP with respect to the pinned layer 108.}

With continuing reference to FIG. 1, the write current (I) required to be generated between the bit line (BL) and the source line (SL) of the MRAM bit cell 102 to change the magnetic orientation of the free layer 112 may be fifty (50) to three hundred (300) micro-Amps (μA) as an example. As fabrication processes allow nodes to be further scaled down in size to reduce area for a given chip or package size, metal interconnection resistance increases due to the reduced cross-sectional area available for metal interconnects in the chip. Thus, for example, if a size of the MRAM bit cell 102 in FIG. 1 is maintained in a given chip or package as node size is scaled down, the amount of write current (I) generated across the STT-MTJ 100 will drop due to the increased resistance in the bit line (BL) and the source line (SL) for a given supply voltage (Vs) (i.e., write current (I)=(V_{SL}−V_{BL})/resistance). Thus, the write current (I) margin of the STT-MTJ 100 is reduced, which can lead to reduced write performance of the MRAM bit cell 102 and yield loss. To solve the issue of increased resistance in the MRAM bit cell 102 due to node size down scaling, the voltage (V_{BL} and V_{SL}) supplied by the peripheral circuits can be increased to maintain the write current (I) to a required current level necessary to perform write operations in the MRAM bit cell 102. However, increasing the supply voltage (Vs) increases power consumption, which may be undesirable. Thus, this increased power consumption can be a limiting factor in an MRAM array size. But in many chip designs, it may not be possible to increase the supply voltage (Vs) because the supply voltage (Vs) is reduced in accordance with general semiconductor technology scaling, for example, to maintain gate dielectric integrity and to reduce overall power consumption in the chip.

### SUMMARY OF THE DISCLOSURE

Aspects of the disclosure involve magnetic random access memory (MRAM) bit cells employing source lines and/or bit lines disposed in multiple, stacked metal layers to reduce MRAM bit cell resistance. Related methods and systems are also disclosed. Metal interconnection resistance of a source line and a bit line in an MRAM bit cell contributes towards the overall resistance of the MRAM bit cell. The resistance of the MRAM bit cell affects the amount of write current generated in the MRAM bit cell for a given voltage applied at an edge of an MRAM array including the MRAM bit cell. As node size is scaled down, metal interconnection resistance increases due to the reduced cross-sectional area available for metal interconnects in an integrated circuit (IC). However, the number of metal wires typically increases, because lithography limitations reduce or eliminate free-formed wiring in the IC and demand increases to couple larger numbers of logic gates through interconnections. Thus, in aspects disclosed herein, these extra stacked metal layers in the IC can be used to form source lines and/or bit lines in MRAM bit cells to compensate for the increased resistance that would otherwise occur in single metal layer source lines and/or bit lines after node size down scaling. By forming the source lines and/or bit lines in multiple, stacked metal layers to maintain or even decrease the resistance of the source line and/or the bit line, the resistance of the MRAM bit cell can be maintained or even reduced, if desired, even as the MRAM bit cell node size is scaled down.

In this regard, in aspects disclosed herein, MRAM bit cells are fabricated in an IC to provide a memory array. In certain aspects disclosed herein, the MRAM bit cells are provided with source lines formed by multiple stacked metal layers disposed above a semiconductor layer to reduce the resistance of the source lines. In other aspects disclosed herein, the bit lines of the MRAM bit cells may also be formed in multiple stacked metal layers disposed above the semiconductor layer to reduce the resistance of the bit lines. In this manner, if the node size in the IC is scaled down, the resistance of the source lines and/or the bit lines can be maintained to maintain the total resistance of the MRAM bit cell read/write path to allow a same, sufficient write current to be generated for write operations for a given drive voltage. Furthermore, if a source line and/or bit line is formed within multiple stacked metal layers in an IC to reduce (rather than maintain) the resistance of the source lines and/or the bit lines, a write driver voltage and/or the IC voltage can be reduced to conserve power while generating a sufficient write current in the MRAM bit cell sufficient for write operations. Or, if it is desired to provide a higher write operating yield for the MRAM bit cell, the resistance of the source lines and/or the bit lines can be reduced without reducing the voltage of the voltage supply to generate an increased write current in the MRAM bit cell.

Further, in other aspects disclosed herein, to compensate or offset an otherwise resistance imbalance between a source line and a bit line in an MRAM bit cell that results from a typical MRAM bit cell layout in an IC providing narrower source lines than bit lines, the source lines and/or bit lines provided in the MRAM bit cells disclosed herein may be provided in additional metal layers. Providing the source lines and/or bit lines in additional metal layers can further reduce the resistance of the source lines and/or bit lines to provide a greater resistance balance between the source lines and the bit lines in the MRAM bit cells, thereby allowing drive voltage in a write driver circuit to be decreased. This is because resistance imbalance between source lines and bit lines in an MRAM array causes additional loss in write current margin, which have to be provided in a writer driver circuit during write operations to compensate for the resulting increase in the overall resistance difference between MRAM bit cells located nearer and farther away from the write driver circuit. Resistance imbalance between source lines and bit lines in an MRAM array can also increase signal degradation during read operations.

Note that although MRAM, and particularly STT-MRAM, is used to illustrate certain aspects and benefits of the present disclosure, the present disclosure is not limited to MRAM or STT-MRAM. The present disclosure can be applied to any other on-chip (i.e., embedded) memory bit cells that require bipolar and significant electrical current for read and/or write operations.

In this regard, in one aspect, an integrated circuit (IC) comprising at least one magnetic random access memory (MRAM) bit cell is provided. The at least one MRAM bit cell comprises an access transistor disposed in a semiconductor layer of the IC, the access transistor comprising a gate, a source, and a drain. The at least one MRAM bit cell also comprises a magnetic tunnel junction (MTJ) disposed in a metal layer in the IC disposed above the semiconductor layer. The MTJ comprising a first end electrode and a second end electrode. The at least one MRAM bit cell also comprises a drain-side connection column disposed in at least one metal layer in the IC above the semiconductor layer coupling the drain of the access transistor to the first end electrode of the MTJ. The at least one MRAM bit cell also comprises a bit line disposed in at least one metal layer in the IC above the semiconductor layer coupled to the second end electrode of the MTJ. The at least one MRAM bit cell also comprises a source line disposed in a plurality of stacked metal layers in the IC above the semiconductor layer and coupled to the source of the access transistor.

In another aspect, a method of fabricating a MRAM bit cell in an IC is provided. The method comprises forming an access transistor in a semiconductor layer, the access transistor comprising a gate, a source, and a drain. The method also comprises forming a magnetic tunnel junction (MTJ) in a metal layer disposed above the semiconductor layer, the MTJ comprising a first end electrode and a second end electrode. The method also comprises forming a drain-side connection column in at least one metal layer in the IC above the semiconductor layer coupling the drain of the access transistor to the first end electrode of the MTJ. The method also comprises forming a bit line in at least one metal layer above the semiconductor layer coupled to the second end electrode of the MTJ. The method also comprises forming a source line in a plurality of stacked metal layers in the IC above the semiconductor layer coupled to the source of the access transistor.

In another aspect, an IC comprising at least one MRAM bit cell is provided. The at least one MRAM bit cell comprises an access transistor disposed in a semiconductor layer of the IC, the access transistor comprising a gate, a source, and a drain. The at least one MRAM bit cell also comprises a MTJ disposed in a metal layer in the IC disposed above the semiconductor layer. The MTJ comprising a first end electrode and a second end electrode. The at least one MRAM bit cell also comprises a drain-side connection column disposed in at least one metal layer in the IC above the semiconductor layer coupling the drain of the access transistor to the first end electrode of the MTJ. The at least one MRAM bit cell also comprises a source line disposed in at least one metal layers in the IC above the semiconductor layer and coupled to the source of the access transistor. The at least one MRAM bit cell also comprises a bit line disposed in a plurality of stacked metal layers in the IC above the semiconductor layer coupled to the second end electrode of the MTJ.

In another aspect, a method of fabricating a MRAM bit cell in an IC is provided. The method comprises forming an access transistor in a semiconductor layer, the access transistor comprising a gate, a source, and a drain. The method also comprises forming a magnetic tunnel junction (MTJ) in a metal layer disposed above the semiconductor layer, the MTJ comprising a first end electrode and a second end electrode. The method also comprises forming a drain-side connection column in at least one metal layer in the IC above the semiconductor layer coupling the drain of the access transistor to the first end electrode of the MTJ. The method also comprises forming a source line in at least one metal layer above the semiconductor layer coupled to the source of the access transistor. The method also comprises forming a bit line in a plurality of stacked metal layers in the IC above the semiconductor layer coupled to the second end electrode of the MTJ.

### BRIEF DESCRIPTION OF THE FIGURES

FIG. 1 is a schematic diagram of an exemplary magnetic random access memory (MRAM) bit cell that can be provided in an MRAM array in an integrated circuit (IC);

FIG. 2 is a schematic diagram of an exemplary MRAM bit cell in an IC employing a source line and/or a bit line disposed in multiple stacked metal layers to reduce MRAM bit cell resistance for reduced operational power;

FIG. 3 is a schematic diagram of an exemplary MRAM bit cell in an IC with a source line only provided in a first metal layer disposed above a semiconductor layer;

FIG. 4A is a side-view of an exemplary MRAM bit cell stack-up in an IC employing a source line and/or a bit line disposed in multiple stacked metal layers to reduce MRAM bit cell resistance for reduced operational power;

FIG. 4B is a top view of MRAM bit cell layouts in an IC, wherein the MRAM bit cells employ a source line and/or a bit line disposed in multiple stacked metal layers to reduce MRAM bit cell resistance for reduced operational power;

FIG. 4C is a top view of the metal layers of an MRAM bit cell layout of the MRAM bit cells in FIG. 4B;

FIG. 5 is a side-view of another exemplary MRAM bit cell stack-up in an IC employing a source line disposed in multiple stacked metal layers to reduce MRAM bit cell resistance and a MRAM dedicated metal layer for a bit line;

FIG. 6 is a side-view of another exemplary MRAM bit cell stack-up in an IC employing a source line disposed in multiple stacked metal layers to reduce MRAM bit cell resistance and a bit line disposed in multiple, different-sized stacked metal layers;

FIG. 7 is a side view of the exemplary MRAM bit cell stack-up in FIG. 6 employing elongated vias connecting the multiple, different-sized stacked metal layers of the bit line to further reduce resistance of the bit line;

FIG. 8 is a side-view of another exemplary two (2) transistor, two (2) magnetic tunnel junction (MTJ) (2T-2MTJ) MRAM bit cell stack-up in an IC employing source lines disposed in multiple stacked metal layers to reduce MRAM bit cell resistance and a shared bit line; and

FIG. 9 is a block diagram of an exemplary processor-based system that can include a memory system with an MRAM array comprised of MRAM bit cells employing a source line and/or a bit line disposed in multiple stacked metal layers to reduce MRAM bit cell resistance for reduced operational power according to any of the aspects disclosed herein.

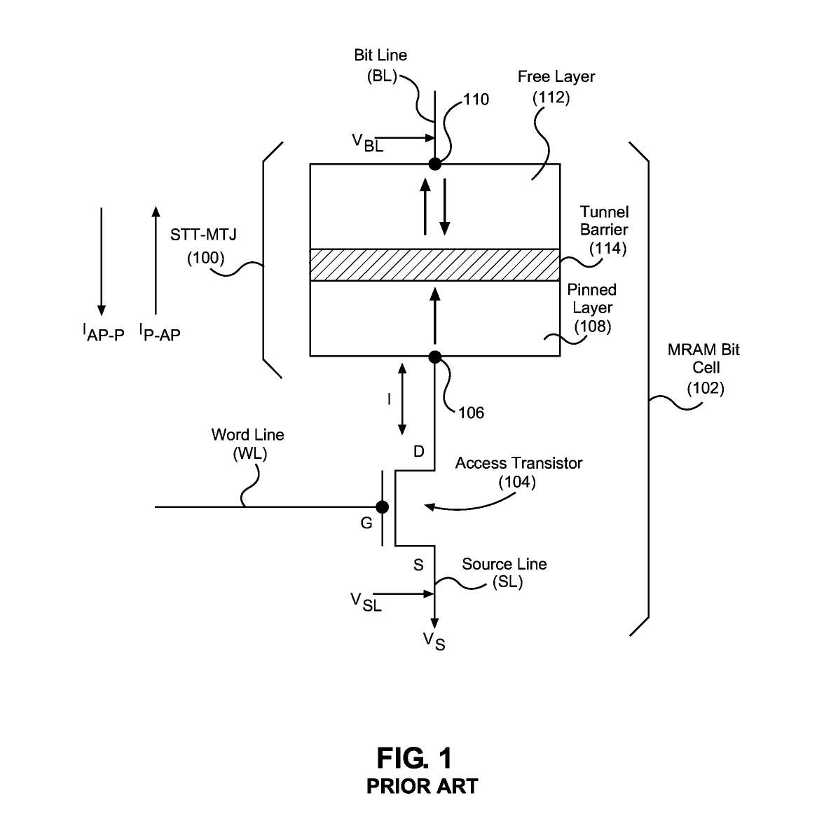

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects of the disclosure involve magnetic random access memory (MRAM) bit cells employing source lines and/or bit lines disposed in multiple, stacked metal layers to reduce MRAM bit cell resistance. Related methods and systems are also disclosed. Metal interconnection resistance of a source line and a bit line in an MRAM bit cell contributes towards the overall resistance of the MRAM bit cell. The resistance of the MRAM bit cell affects the amount of write current generated in the MRAM bit cell for a given voltage applied at an edge of an MRAM array including the MRAM bit cell. As node size is scaled down, metal interconnection resistance increases due to the reduced cross-sectional area available for metal interconnects in an integrated circuit (IC). However, the number of metal wires typically increases, because lithography limitations reduce or eliminate free-formed wiring in the IC and demand increases to couple larger numbers of logic gates through interconnections. Thus, in aspects disclosed herein, these extra stacked metal layers in the IC can be used to form source lines and/or bit lines in MRAM bit cells to compensate for the increased resistance that would otherwise occur in single metal layer source lines and/or bit lines after node size down scaling. By forming the source lines and/or bit lines in multiple, stacked metal layers to maintain or even decrease the resistance of the source line and/or the bit line, the resistance of the MRAM bit cell can be maintained or even reduced, if desired, even as the MRAM bit cell node size is scaled down.

In this regard, in aspects disclosed herein, MRAM bit cells are fabricated in an IC to provide a memory array. In certain aspects disclosed herein, the MRAM bit cells are provided with source lines formed by multiple stacked metal layers disposed above a semiconductor layer to reduce the resistance of the source lines. In other aspects disclosed herein, the bit lines of the MRAM bit cells may also be formed in multiple stacked metal layers disposed above the semiconductor layer to reduce the resistance of the bit lines. In this manner, if the node size in the IC is scaled down, the resistance of the source lines and/or the bit lines can be maintained to maintain the total resistance of the MRAM bit cell read/write path to allow a same, sufficient write current to be generated for write operations for a given drive voltage. Furthermore, if a source line and/or bit line is formed within multiple stacked metal layers in an IC to reduce (rather than maintain) the resistance of the source lines and/or the bit lines, a write driver voltage and/or the IC voltage can be reduced to conserve power while generating a sufficient write current in the MRAM bit cell sufficient for write operations. Or, if it is desired to provide a higher write operating yield for the MRAM bit cell, the resistance of the source lines and/or the bit lines can be reduced without reducing the voltage of the voltage supply to generate a sufficient write current in the MRAM bit cell.

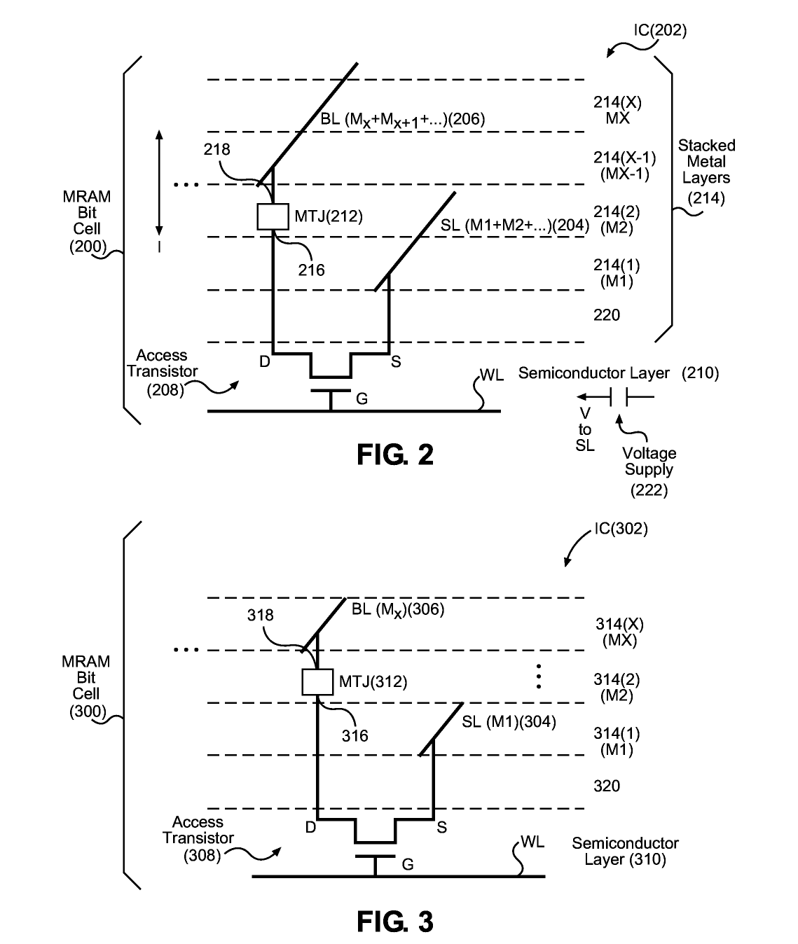

In this regard, FIG. 2 is a schematic diagram of an exemplary MRAM bit cell 200 in an IC 202. For example, the IC 202 may be a system-on-a-chip (SoC). The MRAM bit cell 200 employs a source line (SL) 204 and a bit line (BL) 206 disposed in multiple stacked metal layers to reduce the MRAM bit cell 200 resistance for reduced operational power. The MRAM bit cell 200 in FIG. 2 comprises an access transistor 208 disposed in a semiconductor layer 210 of the IC 202. The access transistor 208 comprises a gate (G), a drain node (D) as a first current electrode, and a source node (S) as a second current electrode. The MRAM bit cell 200 also comprises a magnetic tunnel junction (MTJ) 212. The MTJ 212 is disposed in an upper metal layer 214 of multiple stacked metal layers 214(1)-214(X) (M1-MX) of the IC 202 above the semiconductor layer 210, which is the upper metal layer 214(2) in this example. The MTJ 212 comprises a first end electrode 216 coupled to the drain node (D) of the access transistor 208 and a second end electrode 218 coupled to the bit line 206. The first end electrode 216 may be coupled to the drain node (D) by a via or metal layer 220 disposed above the semiconductor layer 210. The MRAM bit cell 200 also provides the source line 204 coupled to the source node (S) of the access transistor 208. To perform a write operation on the MRAM bit cell 200 to change the magnetization state of the MTJ 212, the word line (WL) is activated to activate the access transistor 208. This causes a voltage (V) from a write driver voltage supply and/or a voltage supply 222 (hereinafter “voltage supply 222”) supplying voltage (V) to the IC 202, to be applied between the source line 204 and the bit line 206 of the MRAM bit cell 200, thus generating the write current (I) through the MTJ 212 as a result of the resistance of the MTJ 212.

Note that in an alternative design of the MRAM bit cell 200 in FIG. 2, the first end electrode 216 could be coupled to the source node (S) of the access transistor 208, and the source line 204 could be coupled to the drain node (D) of the access transistor 208, such as if a free layer (not shown) in the MTJ 212 was provided adjacent to the first end electrode 216.

With continuing reference to FIG. 2, to maintain or reduce the resistance of the source line 204 and/or bit line 206 of the MRAM bit cell 200 as the MRAM bit cell 200 is scaled down in size, the source line 204 and/or bit line 206 is disposed in a plurality of stacked metal layers 214 disposed above the semiconductor layer 210. In this example of the MRAM bit cell 200 in FIG. 2, the source line 204 is disposed in multiple stacked metal layers 214(1), 214(2) disposed above the semiconductor layer 210, also known as metal layer 1 (M1) and metal layer 2 (M2). In this regard, the resistance of the source line 204 can be maintained or reduced as the MRAM bit cell 200 is scaled down in size to avoid having to increase the voltage provided at an edge of an MRAM array including the MRAM bit cell 200 to generate the desired write current (I). The MRAM bit cell 200 also comprises the bit line 206 coupled to the second end electrode 218 of the MTJ 212. The bit line 206 is disposed in at least one metal layer 214 in the IC 202 disposed above the upper metal layer 214(2) of the IC 202. In this example, while not required, the bit line 206 is also disposed in multiple stacked metal layers 214(X−1)-214(X), where ‘X’ can signify any number index of stacked metal layers 214 disposed in the IC 202. In this regard, the resistance of the bit line 206 can also be maintained or reduced as the MRAM bit cell 200 is scaled down in size.

In this manner, if the node size in the IC 202 is scaled down in FIG. 2, the resistance of the source line 204 and/or the bit line 206 of the MRAM bit cell 200 can be maintained to maintain the total resistance of the MRAM bit cell 200 to allow the same, sufficient write current to be generated for write operations for a given drive voltage. However, if multiple stacked metal layers 214 are arranged in a scaled down IC 202 to reduce (rather than maintain) the resistance of the source line 204 and/or the bit line 206, the voltage (V) supplied by the voltage supply 222 can be reduced to conserve power while generating a sufficient write current (I) in the MRAM bit cell 200 sufficient for write operations. Or, if it is desired to provide a higher write operating yield for the MRAM bit cell 200, the resistance of the source line 204 and/or the bit line 206 can be reduced without reducing the voltage (V) from the voltage supply 222 to generate an increased write current (I) in the MRAM bit cell 200.

Thus, by providing the MRAM bit cell 200 in FIG. 2 with the source line 204 and/or the bit line 206 disposed in multiple stacked metal layers 214 to maintain or reduce MRAM bit cell resistance, other techniques do not have to be employed to compensate for an increase in MRAM bit cell resistance that would otherwise occur from MRAM bit cell size down scaling. For example, although not limiting, MRAM bit cell width would not have to be increased to provide for an increased width and decreased resistance source line and/or bit cell to compensate for MRAM bit cell size down scaling, that would otherwise cause the MRAM bit cells in an IC to consume more area. As another example, although not limiting, it would not be necessary to provide an increased voltage across the MRAM bit cell to maintain the write current applied to the MRAM bit cell for the increased resistance in the MRAM bit cell. For example, a voltage supply could be provided in the IC to increase the voltage applied to the MRAM bit cells at the cost of higher power consumption for the IC. Even if a special, additional voltage supply were provided to apply an increased voltage to MRAM bit cells only for write operations, this would still increase power consumption and require an additional complexity in providing the additional voltage supply and voltage switching for write operations.

To contrast the MRAM bit cell 200 in FIG. 2, FIG. 3 is a schematic diagram of an MRAM bit cell 300 in an IC 302 with a source line (SL) 304 and a bit line (BL) 306 only provided in a single metal layer 314, which is metal layer 314(X) (MX) in FIG. 3. The source line is disposed in a first metal layer 314(1) (M1) above a semiconductor layer 310. The bit line 306 is disposed in a higher metal layer (MX) above the MTJ 312. In this manner, if the node size of the MRAM bit cell 300 in the IC 302 were scaled down, the resistance of the source line 304 may not be maintained, because the source line 304 and the bit line 306 will be reduced in thickness as a result of the down scaling. However, if the source line 304 and/or the bit line 306 were provided in additional metal layer 314, as shown in the MRAM bit cell 200 in FIG. 2, the otherwise increased resistance of the source line 304 and/or bit line 306 resulting from down scaling could be offset to maintain the resistance of the MRAM bit cell 300, or the resistance of the source line 304 and/or bit line 306 could even be reduced.

Similar to the MRAM bit cell 200 in FIG. 2, the MRAM bit cell 300 in FIG. 3 comprises an access transistor 308 disposed in the semiconductor layer 310 of the IC 302. The access transistor 308 comprises a gate (G), a drain node (D) as a first current electrode, and a source node (S) as a second current electrode. The MRAM bit cell 300 also comprises a MTJ 312. The MTJ 312 is disposed in an upper layer 314(2) of the IC 302 above the semiconductor layer 310 in this example. The MTJ 312 comprises a first end electrode 316 coupled to the drain node (D) of the access transistor 308, and a second end electrode 318 coupled to the bit line 306. The first end electrode 316 may be coupled to the drain node (D) by a via or metal layer 320 disposed above the semiconductor layer 310. The MRAM bit cell 300 also provides the source line 304 coupled to the source node (S) of the access transistor 308.

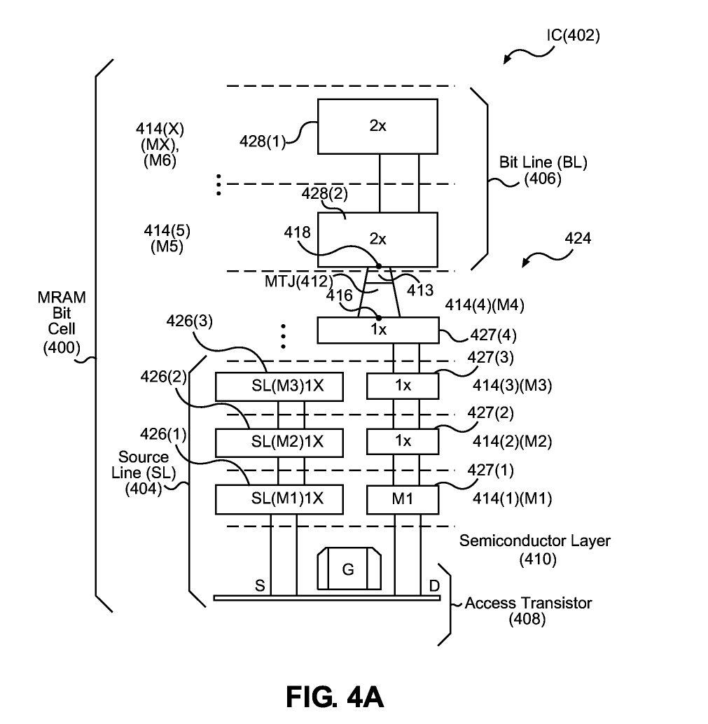

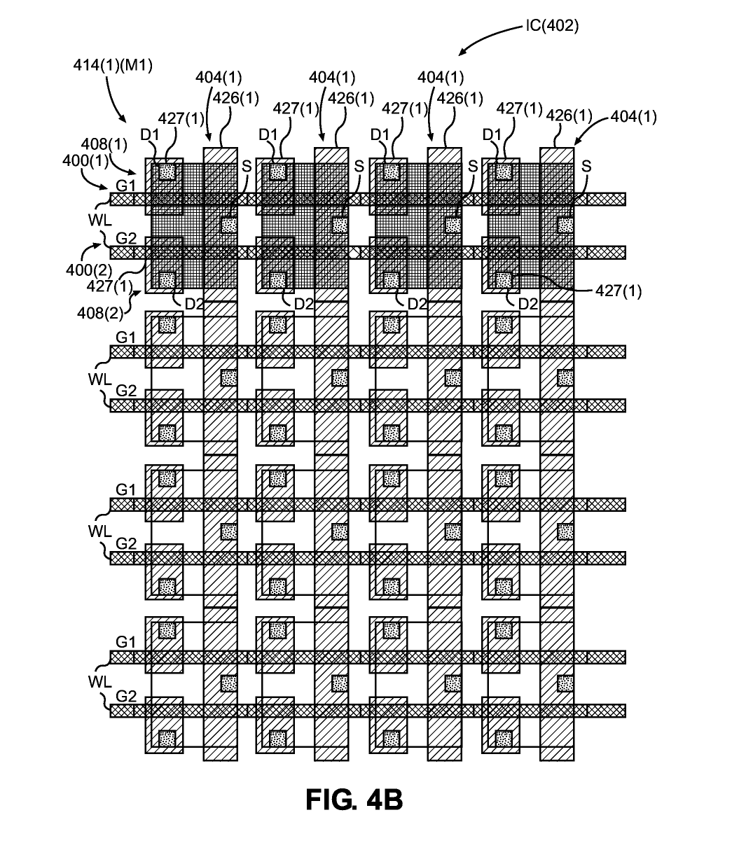

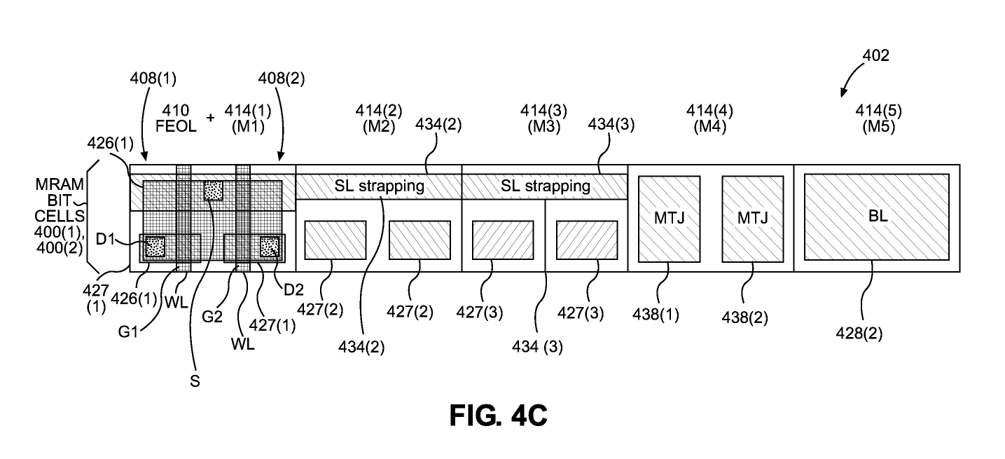

To further illustrate an example of disposing a source line and/or a bit line of an MRAM bit cell in a plurality of stacked layers disposed above a semiconductor layer to maintain or reduce the resistance of the source line and/or the bit line, FIGS. 4A and 4B are provided. FIG. 4A is a side-view of an exemplary MRAM bit cell stack-up 424 of an MRAM bit cell 400 in an IC 402 employing a source line (SL) 404 and a bit line (BL) 406 both disposed in multiple, stacked metal layers 414(1)-414(X) (M1-MX) to reduce the MRAM bit cell 400 resistance. As discussed in more detail below, the MRAM bit cell 400 employs the source line 404 and the bit line 406 disposed in the multiple, stacked metal layers 414 (M) to maintain or reduce the resistance of the source line 404 and the bit line 406 of the MRAM bit cell 400.

The MRAM bit cell 400 in FIG. 4A comprises an access transistor 408 disposed in a semiconductor layer 410 of the IC 402. The access transistor 408 comprises a gate (G), a drain node (D) as a first current electrode, and a source node (S) as a second current electrode. The MRAM bit cell 400 also comprises an MTJ 412. A hard mask 413 may be disposed on the MTJ 412 stack-up during an etching process of forming the MTJ 412. The MTJ 412 is disposed in an upper metal layer 414(4), which is metal layer four (M4) in this example, of the IC 402 above the semiconductor layer 410. The MTJ 412 comprises a first end electrode 416 coupled to the drain node (D) of the access transistor 408, and a second end electrode 418 coupled to the bit line 406. The first end electrode 416 is coupled to the drain node (D) by a via or metal layer 414(1) (M1) disposed above the semiconductor layer 410. The MRAM bit cell 400 also provides the source line 404 coupled to the source node (S) of the access transistor 408.

With continuing reference to FIG. 4A, to maintain or reduce the resistance of the source line 404 of the MRAM bit cell 400, as the MRAM bit cell 400 is scaled down in size, the source line 404 is disposed in a plurality of stacked metal layers 414 (M) disposed above the semiconductor layer 410. In this example, the source line 404 is disposed in stacked metal layers 414(1)-414(3) (M1-M3) disposed above the semiconductor layer 410, also known as metal layers M1-M3. The MRAM bit cell 400 also comprises the bit line 406 coupled to the second end electrode 418 of the MTJ 412. The bit line 406 is disposed in at least one metal layer 414(M) in the IC 402 disposed above the upper metal layer 414(4) (M4) of the IC 402. In this example, the bit line 406 is disposed in stacked metal layers 414(5)-414(X) (MX−1-MX), which are the fifth and sixth metal layers (M5 and M6) in the IC 402 in this example. In this regard, the resistance of the bit line 406 can be maintained or reduced as the MRAM bit cell 400 is scaled down in size.

Even when providing the source line 404 and/or the bit line 406 of the MRAM bit cell 400 in multiple stacked metal layers 414 (M) in the IC 402, a resistance imbalance between the source line 404 and the bit line 406 may exist if the MRAM bit cell 400 is provided in a typical layout with narrower source lines than bit lines. As an example, resistance imbalance between the source line 404 and the bit line 406 in the MRAM bit cell 400 can cause an overall resistance difference in the MRAM bit cells 400 included in an MRAM array located nearer and farther away from a write driver circuit. Resistance imbalance between the source line 404 and the bit line 406 in the MRAM bit cell 400 can also increase signal degradation during read operations.

In this regard, in the exemplary MRAM bit cell 400 in FIG. 4A, the source line 404 and the bit line 406 are disposed in multiple stacked metal layers 414 (M) such that the resistance of the source line 404 and the resistance of the bit line 406 are approximately equal to each other. This provides a more balanced resistance between the source line 404 and the bit line 406 in the MRAM bit cell 400. The resistances of the source line 404 and the bit line 406 in the MRAM bit cell 400 are balanced or substantially balanced in this example by providing the source line 404 and the bit line 406 in the stacked metal layers 414 (M) that compensate for the differences in length and conductivity between the source line 404 and the bit line 406, as compared to a typical MRAM bit cell layout like the MRAM bit cell 300 in FIG. 3.

With continuing reference to FIG. 4A, to provide for the resistance of the source line 404 to be balanced or substantially balanced with the resistance of the bit line 406, or reduce the imbalance thereof, the bit line 406 can be disposed in a fewer number of stacked metal layers 414(X−1)-414(X) (MX−1-MX) than the source line 404 disposed in metal layers 414(1)-414(3) (M1-M3). In this example, the source line 404 is disposed in metal lines 426(1)-426(3) in a height of a dense-pitch metal layer (noted as “1X” height) of the IC 402. The metal lines 426(1)-426(3) are electrically coupled to each other in metal layers 414(1)-414(3) (M1-M3). A drain-side connection column provided in the form of electrical coupled metal lines 427(1)-427(4) are provided in metal layers 414(1)-414(4) (M1-M4), respectively, to connect the drain (D) to the MTJ 412. As an example, the metal lines 426(1)-426(3) and 427(1)-427(4) may be provided as copper lines and islands in the IC 402. The metal lines 426(1)-426(3) are provided to have less conductivity than stacked metal lines 428(1)-428(2) electrically coupled to each other providing the bit line 406. However, by the source line 404 in the MRAM bit cell 400 being disposed in more metal lines 426(1)-426(3) than the bit line 406, the resistance of the source line 404 and the bit line 406 can be provided to be balanced or substantially balanced. In this example, the metal lines 426(1)-426(3) may be approximately half the height (1X height) of the metal lines 428(1)-428(2) if the metal lines 428(1)-428(2) are using twice the pitch of the metal lines 426(1)-426(3) (the height of metal levels such as the metal lines 428(1)-428(2) is noted as “2X” height). The width of the metal lines 428(1)-428(2) are approximately 1.5 times the width of the metal lines 426(1)-426(3). Thus each metal line 428 has approximately three (3) times the conductivity of each metal line 426 in this example. Note that metal line 428(1) may be omitted in such an example to achieve substantially equal resistance on the source line 404 and the bit line 406. Note that the source line 404 can extend to higher metal layers 414 (M) in additional metal lines 426 than illustrated in FIG. 4A, including to provide a balanced resistance between the source line 404 and the bit line 406. The source line 404 can be provided in higher metal layers 414 (M) as long as a desired pitch can be maintained between the metal lines 426 for the source line 404, and the metal lines 427 connecting the drain (D) to the MTJ 412 as the drain-side connection column, and the metal lines 428 of the bit line 406.

Note that with continuing reference to FIG. 4A, the height of metal line(s) 428 used to provide the bit line 406 is not limited to “2X” that of the metal lines 426 for the source line 404. For example, a single metal line 428 could be employed to provide the bit line 404. The height of the metal line(s) 428 used to provide the bit line 406 could be 1.25X or any other height desired according to the desired operational characteristics of the MRAM bit cell 400, including balancing of the resistance of the source line 404 and bit line 406.

FIG. 4B is a top view of the IC 402 that illustrates an MRAM bit cell layout for MTJ bit cells that can include the MRAM bit cells 400 like that shown in FIG. 4A. In this regard, groupings of two MRAM bitcells 400(1), 400(2) are provided that share a common source (S). Each MRAM bitcells 400(1), 400(2) includes an access transistor 408(1), 408(2). The access transistors 408(1), 408(2) each have respective drains (D1, D2) and gates (G1, G2), and a common source (S). As discussed above, the MRAM bit cell 400 in FIG. 4A includes MRAM bit cell stack-ups 424 each employing its source line 404 and bit line 406 disposed in multiple stacked metal layers 414 to reduce MRAM bit cell 400 resistance for reduced operational power.

In FIG. 4B, only the first metal layer 414(1) (MD is shown, but other metals layers 414(2)-414(X) (M2-MX) would be above the first metal layer 414(1). Metal layers 414(2)-414(3) (M2-M3) can have the same layout in the IC 402 as metal layer 414(1) (M1). For example, with reference to FIG. 4B, the source lines 404 (shown in FIG. 4A) and the metal layer 414(1) (MD in the MRAM bit cells 400(1), 400(2) can use metal lines 426 in stacked metal layers 414(1)-414(3) (only metal line 426(1) for metal layer 414(1) shown in FIG. 4C). The bit lines 406 in the MRAM bit cells 400(1), 400(2) can use metal lines 427 for the drain-side connection column that are provided to be twice as wide as the metal lines 426 used for the source line 404. In this example, the total conductance of the source line 404 and the total conductance of the bit line 406 are made substantially equal in a typical logic process.

FIG. 4C is a top view of the metal layers 414(1)-414(5) (M1-M5) illustrating the layout of two MRAM bit cells 400(1), 400(2) in FIG. 4B to provide additional detail. As shown in FIG. 4C, the access transistors 408(1), 408(2) and their respective drain (D), sources (S1, S2), and gates (G1, G2) (which are tied together) are provided in the semiconductor layer 410 in a front end-of-line (FEOL) fabrication process. The first metal layer 414(1) (M1) disposed above the semiconductor layer 410 is provided and connected to the source (S) and drains (D1, D2) via contact pads. The metal line 426(1) as part of the source line 404 to connect to the source (S) in the semiconductor layer 410 is provided in the first metal layer 414(1) (M1). The metal line 428(1) to connect to the respective drains (D1, D2) of the access transistors 408(1), 408(2) in the semiconductor layer 410 is also provided in the first metal layer 414(1) (M1).

With continuing reference to FIG. 4C, the metal lines 427(2), 427(2) are provided in the second metal layer 414(2) (M2) as part of the drain-side connection column for the respective drains (D1, D2). Source strapping lines 434(2)-434(3) are provided in the second metal layer 414(2) (M2) and the third metal layer 414(3) (M3) to strap or couple the metal line 426(1) for the respective MRAM bit cells 400(1), 400(2), to strap to the source (S) in multiple stacked metal layers in the IC 402. The metal lines 427(2), 427(3) are provided in the second metal layer 414(2) (M2) and the third metal layer 414(3) (M3) to strap or couple to the drain metal line 427(1) for the respective MRAM bit cells 400(1), 400(2) to strap the drains (D1, D2) to respective MTJ landing pads 438(1), 438(2) for each MRAM bit cell 400(1), 400(2) in the fourth metal layer 414(4) (M4), as shown in FIG. 4C. The metal line 428(2) of the bit line 406 is provided in the fifth metal layer 414(5) (M5) above the MTJ landing pads 438(1), 438(2) for each MRAM bit cell 400(1), 400(2).

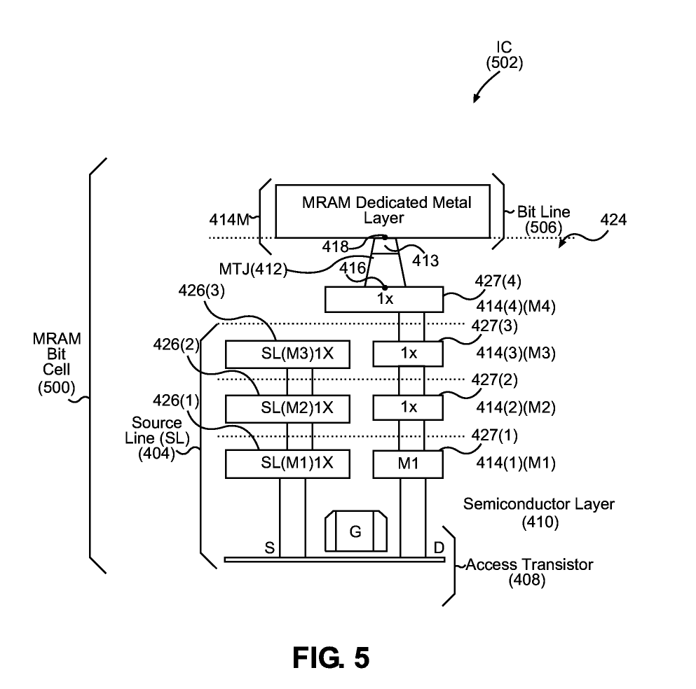

Other variations of providing MRAM bit cells having a source line and/or a bit line provided among a plurality of stacked layers disposed above a semiconductor layer to maintain or reduce the resistance of the source line and/or the bit line are possible. For example, FIG. 5 illustrates an MRAM bit cell 500 in an IC 502 that is similar to the MRAM bit cell 400 in FIG. 4A. Common elements between the MRAM bit cell 500 in FIG. 5 and the MRAM bit cell 400 in FIG. 4A are shown with common element numbers between FIGS. 4A and 5, and thus will not be re-described. As shown in FIG. 5, the MRAM bit cell 500 includes an MRAM dedicated metal layer 414M for providing part or all of the bit line 506. For example, the MRAM dedicated metal layer 414M could be provided as a dedicated wiring level instead of using a metal layer used for standard logic circuits. Providing an MRAM dedicated metal layer 414M in the MRAM bit cell 500 may allow specific optimizations in terms of design and resistance, because the pattern of the metal layers provided in the IC 502 for the logic components may be randomly provided as part of a layout design or tool operation for the IC 502.

It is to be understood that although a one-transistor-one-MTJ bit cell layout, commonly referred to as “1T1J” or “1T1MTJ,” is used to illustrate the example of the MRAM bit cell 400 in FIG. 4A, the aspects of the MRAM bit cells disclosed herein can be applied to any MRAM bit cell or array architecture. It may be desired to employ the aspects disclosed herein for MRAM bit cell architectures in which source line or bit line resistance negatively impacts write margin, power consumption, or any other aspect of a device employing MRAM bit cells. For example, without limitation, a bit cell architecture with common source line could employ source lines and/or bit lines disposed in multiple stacked metal layers to reduce MRAM bit cell resistance for reduced operational power according to aspects disclosed herein. Also as an example, without limitation, a two transistor, two MTJ (2T-2MTJ) bit cell architecture could employ source lines and/or bit lines disposed in multiple stacked metal layers to reduce MRAM bit cell resistance for reduced operational power according to aspects disclosed herein.

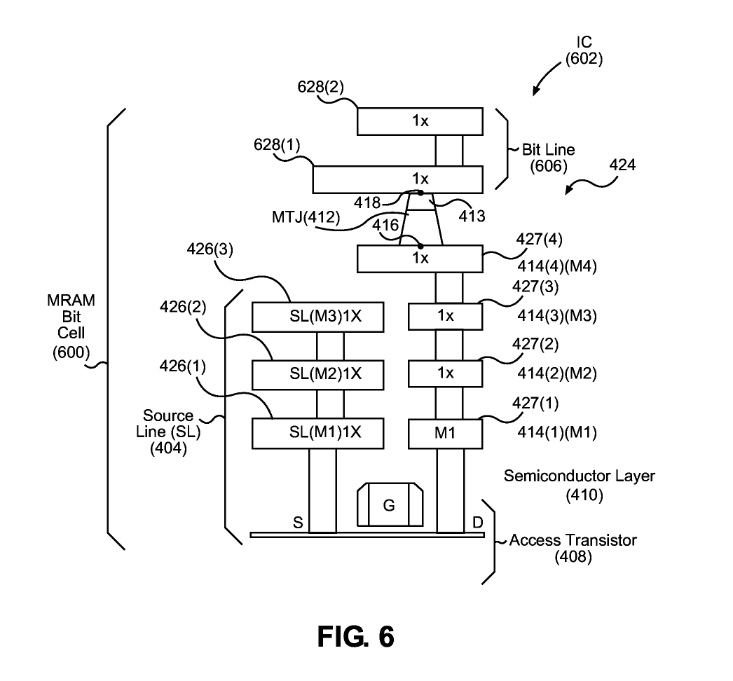

The metal lines used to provide the source line and/or the bit line in an MRAM bit cell employing the source line and/or bit line in multiple stacked metal layers to reduce MRAM bit cell resistance can also be differently sized according to the desired resistance characteristic. In this regard, FIG. 6 is a side-view of another exemplary MRAM bit cell 600 in an IC 602 employing the source line 404 disposed in multiple stacked metal layers to reduce MRAM bit cell resistance. Common elements between the MRAM bit cell 600 in FIG. 6 and the MRAM bit cell 400 in FIG. 4A are shown with common element numbers between FIGS. 4A and 6, and thus will not be re-described. The MRAM bit cell 600 in FIG. 6 also includes a bit line 606 that is disposed in multiple, different-sized stacked metal layers. However, the bit line 606 is provided in different metal lines 628 in metal layers 414(X−1) (MX−1) and 414(X) (MX) that are differently sized from each other. For example, the width of the metal line 628(1) provided in metal layer 414(X−1) (MX−1) as part of the bit line 606 is approximately 2.5 times longer than the width of the metal lines 426. The width of the metal line 628(2) is approximately 1.5 times longer than the width of the metal lines 426.

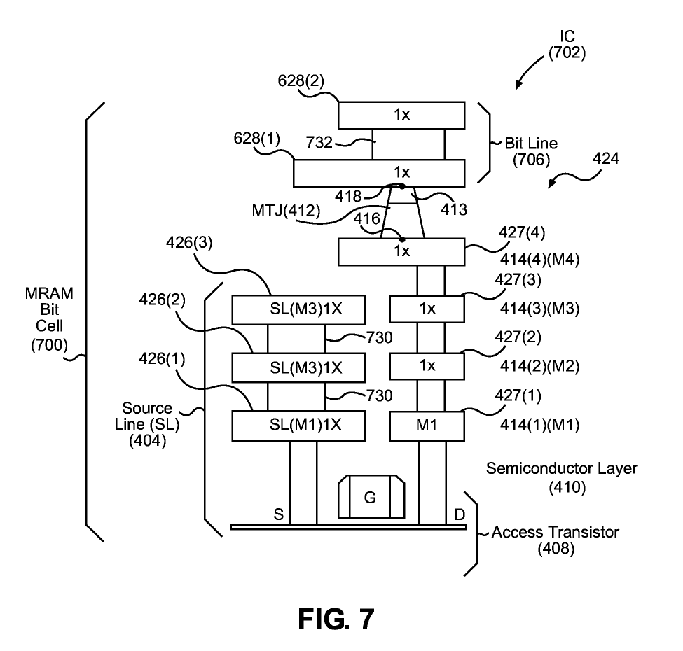

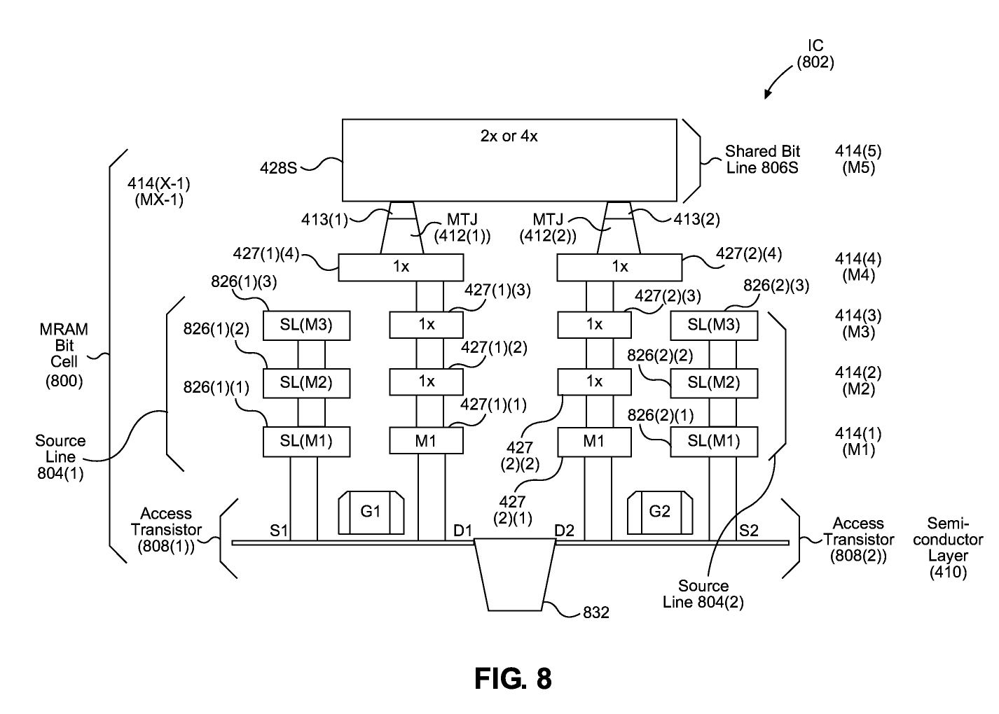

Vias that are provided in MRAM bit cells to interconnect different metal lines in different stacked metal layers (M) for providing a source line and/or a bit line to decrease MRAM bit cell resistance can also be modified to reduce via resistance and thus overall MRAM bit cell resistance. In this regard, FIG. 7 is a side view of the exemplary MRAM bit cell 700 in an IC 702 similar to the MRAM bit cell 600 in FIG. 6. Common elements between the MRAM bit cell 700 in FIG. 7 and the MRAM bit cell 600 in FIG. 6 are shown with common element numbers between FIGS. 6 and 7, and thus will not be re-described. However, the MRAM bit cell 700 in FIG. 7 employs an elongated via(s) 730 connecting the metal lines 426(1)-426(3) of the source line 404 to further reduce resistance of the source line 404 and the MRAM bit cell 700. In this example, the MRAM bit cell 700 in FIG. 7 employs also employs an elongated via(s) 732 connecting the multiple, different sized metal lines 628(1), 628(2) of the bit line 706 to further reduce resistance of the bit line 706 and the MRAM bit cell 700. An elongated via is a via that is substantially longer in the length direction than its width direction. In the example in FIG. 7, the width of the vias 730, 732 are elongated to decrease the resistance of the source line 404 versus what its resistance would be if the vias 730, 732 were not elongated like shown in MRAM bit cell 600 in FIG. 6. In the example in FIG. 7, the vias 730, 732 are fabricated to be rectangular-shaped to be elongated.

MRAM bit cells having a shared source line and/or a bit line provided among a plurality of stacked layers disposed above a semiconductor layer to maintain or reduce the resistance of the source line and/or the bit line can also be provided. In this regard, FIG. 8 is a side-view of an exemplary two (2) transistor, two (2) MTJ (2T-2MTJ) MRAM bit cell 800 in an IC 802. The 2T-2MTJ MRAM bit cell 800 provides two access transistors 808(1), 808(2) each having their own respective sources (S1, S2), drains (D1, D2), and gates (G1, G2) isolated by a shallow trench 832 to provide shallow trench isolation (STI). The 2T-2MTJ MRAM bit cell 800 employs two source lines 804(1), 804(2) disposed in multiple stacked metal layers 414 to reduce MRAM bit cell resistance similar to those provided in the MRAM bit cell 400 in FIG. 4A. Common elements between the MRAM bit cell 800 in FIG. 8 and the MRAM bit cell 400 in FIG. 4A are shown with common element numbers between FIGS. 4A and 8, and thus will not be re-described. The source lines 804(1), 804(2) are provided in respective metal lines 826(1)(1)-826(1)(3), 826(2)(1)-826(2)(3) over multiple metal layers 414(1)-414(3) (M1-M3), similar to the source line 404 in the MRAM bit cell 400 in FIG. 4A. Respective metal lines 427(1)(1)-427(1)(4), 427(2)(1)-427(2)(4) are provided over multiple metal layers 414(1)-414(4) (M1-M4) to couple the respective MTJs 412(1), 412(2) to the drains (D1, D2). However, a shared bit line 806S is provided in the 2T-2MTJ MRAM bit cell 800 in FIG. 8. The shared bit line 806 is provided in a shared metal line 428S in the metal layer 414(X−1) (MX−1) disposed just above where the MTJs 412(1), 412(2) are located. The shared bit line 806S can be sized in width and/or length to provide the desired bit line resistance for the 2T-2MTJ MRAM bit cell 800 and/or in reference to the resistance of the source lines 804(1), 804(2) of the 2T2-MTJ MRAM bit cell 800, as desired.

The MRAM bit cells employing source lines and/or bit lines disposed in multiple stacked metal layers to reduce MRAM bit cell resistance for reduced operational power according to aspects disclosed herein, may be provided in or integrated into in any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

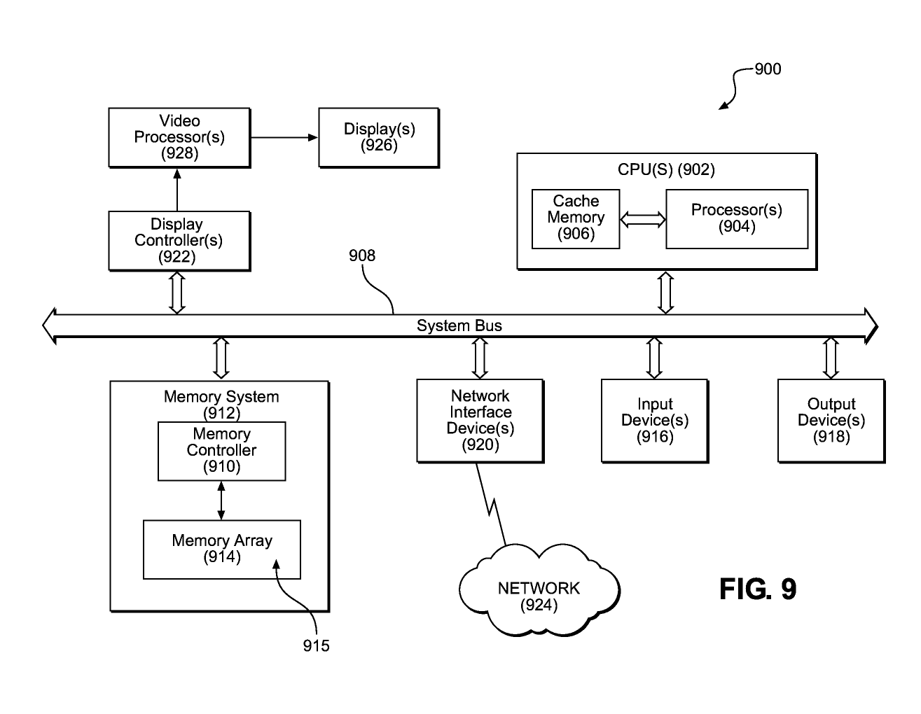

In this regard, FIG. 9 illustrates an example of a processor-based system 900 that can employ a memory system with a memory array employing MRAM bit cells employing source lines and/or bit lines disposed in multiple stacked metal layers to reduce MRAM bit cell resistance for reduced operational power according to any of the particular aspects discussed above. In this example, the processor-based system 900 includes one or more central processing units (CPUs) 902, each including one or more processors 904. The CPU(s) 902 may have cache memory 906 coupled to the processor(s) 904 for rapid access to temporarily stored data. The CPU(s) 902 is coupled to a system bus 908 and can intercouple master and slave devices included in the processor-based system 900. As is well known, the CPU(s) 902 communicates with these other devices by exchanging address, control, and data information over the system bus 908. For example, the CPU(s) 902 can communicate bus transaction requests to a memory controller 910 in a memory system 912 as an example of a slave device. Although not illustrated in FIG. 9, multiple system buses 908 could be provided, wherein each system bus 908 constitutes a different fabric. In this example, the memory controller 910 is configured to provide memory access requests to a memory array 914 in the memory system 912. The memory array 914 can include MRAM bit cells 915 that can employ source lines and/or bit lines disposed in multiple stacked metal layers to reduce MRAM bit cell 915 resistance. The cache memory array 906 could also include MRAM bit cells that can employ source lines and/or bit lines disposed in multiple stacked metal layers to reduce MRAM bit cell resistance.

Other devices can be connected to the system bus 908. As illustrated in FIG. 9, these devices can include the memory system 912, one or more input devices 916, one or more output devices 918, one or more network interface devices 920, and one or more display controllers 922, as examples. The input device(s) 916 can include any type of input device, including but not limited to input keys, switches, voice processors, etc. The output device(s) 918 can include any type of output device, including but not limited to audio, video, other visual indicators, etc. The network interface device(s) 920 can be any devices configured to allow exchange of data to and from a network 924. The network 924 can be any type of network, including but not limited to a wired or wireless network, a private or public network, a local area network (LAN), a wide local area network (WLAN), and the Internet. The network interface device(s) 920 can be configured to support any type of communications protocol desired.

The CPU(s) 902 may also be configured to access the display controller(s) 922 over the system bus 908 to control information sent to one or more displays 926. The display controller(s) 922 sends information to the display(s) 926 to be displayed via one or more video processors 928, which process the information to be displayed into a format suitable for the display(s) 926. The display(s) 926 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An integrated circuit (IC) comprising at least one magnetic random access memory (MRAM) bit cell, the at least one MRAM bit cell, comprising:
an access transistor disposed in a semiconductor layer of the IC, the access transistor comprising a gate, a source, and a drain;
a magnetic tunnel junction (MTJ) disposed in a metal layer in the IC disposed above the semiconductor layer, the MTJ comprising a first end electrode and a second end electrode;
a drain-side connection column disposed in at least one metal layer in the IC above the semiconductor layer coupling the drain of the access transistor to the first end electrode of the MTJ;
a bit line disposed in at least one metal layer in the IC above the semiconductor layer coupled to the second end electrode of the MTJ; and
a source line disposed in a plurality of stacked metal layers in the IC above the semiconductor layer and coupled to the source of the access transistor.

2. The IC of claim 1, wherein the source line comprises a plurality of stacked metal lines disposed in the plurality of stacked metal layers and electrically coupled together.

3. The IC of claim 2, wherein at least two metal lines among the plurality of stacked metal lines of the source line have different lengths from each other.

4. The IC of claim 2, wherein at least two metal lines among the plurality of stacked metal lines of the source line have different widths from each other.

5. The IC of claim 2, wherein at least two metal lines among the plurality of stacked metal lines of the source line have different lengths and widths from each other.

6. The IC of claim 2, further comprising at least one elongated via disposed in the IC between at least two metal lines among the plurality of stacked metal lines of the source line, the at least one elongated via electrically coupling the at least two metal lines among the plurality of stacked metal lines of the source line together.

7. The IC of claim 1, wherein the bit line is disposed in a plurality of stacked metal layers in the IC disposed above the semiconductor layer.

8. The IC of claim 7, wherein the bit line comprises a plurality of stacked metal lines disposed in the plurality of stacked metal layers and electrically coupled together.

9. The IC of claim 8, wherein at least two metal lines among the plurality of stacked metal lines of the bit line have different lengths and widths from each other.

10. The IC of claim 8, further comprising at least one elongated via disposed in the IC between at least two metal lines among the plurality of stacked metal lines of the bit line, the at least one elongated via electrically coupling the at least two metal lines among the plurality of stacked metal lines of the bit line together.

11. The IC of claim 1, further comprising at least one MRAM dedicated metal layer disposed in the IC, wherein the bit line is disposed in the at least one MRAM dedicated metal layer.

12. The IC of claim 1, wherein:
the at least one MRAM bit cell comprises a plurality of MRAM bit cells; and
the bit line is comprised of a shared bit line coupled between the first end electrode of the MTJs of the plurality of MRAM bit cells and the drain of each access transistor of the plurality of MRAM bit cells.

13. The IC of claim 1, wherein a resistance of the source line and a resistance of the bit line are approximately equal resistances.

14. The IC of claim 1, wherein the MTJ further comprises:
a tunnel barrier between the first end electrode and the second end electrode;
a free layer between the second end electrode and the tunnel barrier; and
a pinned layer between the first end electrode and the tunnel barrier.

15. The IC of claim 1, further comprising a word line disposed in the IC, wherein the word line is coupled to the gate of the access transistor.

16. The IC of claim 1, wherein the at least one MRAM bit cell is comprised of at least one 1T-1MTJ MRAM bit cell.

17. The IC of claim 1, wherein the at least one MRAM bit cell is comprised of at least one 2T-1MTJ MRAM bit cell.

18. The IC of claim 1, wherein the at least one MRAM bit cell is comprised of at least one 2T-2MTJ MRAM bit cell.

19. The IC of claim 1, wherein the at least one MRAM bit cell comprises a plurality of MRAM bit cells in an MRAM array.

20. The IC of claim 1 integrated into a device selected from the group consisting of: a set top box; an entertainment unit; a navigation device; a communications device; a fixed location data unit; a mobile location data unit; a mobile phone; a cellular phone; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; and a portable digital video player.

21. A method of fabricating a magnetic random access memory (MRAM) bit cell in an integrated circuit (IC), comprising:
forming an access transistor in a semiconductor layer, the access transistor comprising a gate, a source, and a drain;
forming a magnetic tunnel junction (MTJ) in a metal layer disposed above the semiconductor layer, the MTJ comprising a first end electrode and a second end electrode;
forming a drain-side connection column in at least one metal layer in the IC above the semiconductor layer coupling the drain of the access transistor to the first end electrode of the MTJ;
forming a bit line in at least one metal layer above the semiconductor layer coupled to the second end electrode of the MTJ; and
forming a source line in a plurality of stacked metal layers in the IC above the semiconductor layer coupled to the source of the access transistor.

22. The method of claim 21, wherein forming the source line comprises forming the source line in a plurality of stacked metal lines electrically coupled together in the plurality of stacked metal layers.

23. The method of claim 22, further comprising forming at least one elongated via disposed in the IC between at least two metal lines among the plurality of stacked metal lines of the source line to couple the at least two metal lines among the plurality of stacked metal lines of the source line together.

24. The method of claim 21, wherein forming the bit line comprising forming the bit line in a plurality of stacked metal layers in the IC disposed above the semiconductor layer.

25. The method of claim 24, wherein forming the bit line comprises forming a plurality of stacked metal lines disposed in the plurality of stacked metal layers electrically coupled together.

26. The method of claim 25, further comprising forming at least one elongated via disposed in the IC between at least two metal lines among the plurality of stacked metal lines of the bit line to electrically couple the at least two metal lines among the plurality of stacked metal lines of the bit line together.

27. The method of claim 21, wherein forming the bit line comprises forming at least one MRAM dedicated metal layer disposed in the IC above the semiconductor layer coupled to the second end electrode of the MTJ.

28. The method of claim 21, further comprising forming a plurality of the MRAM bit cells in the IC; and
wherein forming the bit line comprises forming a shared bit line coupled between the second end electrode of the MTJs of the plurality of MRAM bit cells.

29. An integrated circuit (IC) comprising at least one magnetic random access memory (MRAM) bit cell, the at least one MRAM bit cell, comprising:
an access transistor disposed in a semiconductor layer of the IC, the access transistor comprising a gate, a source, and a drain;
a magnetic tunnel junction (MTJ) disposed in a metal layer in the IC disposed above the semiconductor layer, the MTJ comprising a first end electrode and a second end electrode;
a drain-side connection column disposed in at least one metal layer in the IC above the semiconductor layer coupling the drain of the access transistor to the first end electrode of the MTJ;
a source line disposed in at least one metal layers in the IC above the semiconductor layer and coupled to the source of the access transistor; and
a bit line disposed in a plurality of stacked metal layers in the IC above the semiconductor layer coupled to the second end electrode of the MTJ.

30. The IC of claim 29, wherein the bit line comprises a plurality of stacked metal lines disposed in the plurality of stacked metal layers and electrically coupled together.

31. The IC of claim 30, wherein at least two metal lines among the plurality of stacked metal lines of the bit line have different lengths from each other.

32. The IC of claim 30, wherein at least two metal lines among the plurality of stacked metal lines of the bit line have different widths from each other.

33. The IC of claim 30, wherein at least two metal lines among the plurality of stacked metal lines of the bit line have different lengths and widths from each other.

34. The IC of claim 30, further comprising at least one elongated via disposed in the IC between at least two metal lines among the plurality of stacked metal lines of the bit line, the at least one elongated via electrically coupling the at least two metal lines among the plurality of stacked metal lines of the bit line together.

35. The IC of claim 29, further comprising at least one MRAM dedicated metal layer disposed in the IC, wherein the bit line is disposed in the at least one MRAM dedicated metal layer.

36. The IC of claim 29, wherein:
the at least one MRAM bit cell comprises a plurality of MRAM bit cells; and
the bit line is comprised of a shared bit line coupled between the first end electrode of the MTJs of the plurality of MRAM bit cells and the drain of each access transistor of the plurality of MRAM bit cells.

37. The IC of claim 29, wherein the MTJ further comprises:
a tunnel barrier between the first end electrode and the second end electrode;
a free layer between the second end electrode and the tunnel barrier; and
a pinned layer between the first end electrode and the tunnel barrier.

38. The IC of claim 29, further comprising a word line disposed in the IC, wherein the word line is coupled to the gate of the access transistor.

39. The IC of claim 29, wherein the at least one MRAM bit cell is comprised of at least one 1T-1MTJ MRAM bit cell.

40. The IC of claim 29, wherein the at least one MRAM bit cell is comprised of at least one 2T-1MTJ MRAM bit cell.

41. The IC of claim 29, wherein the at least one MRAM bit cell is comprised of at least one 2T-2MTJ MRAM bit cell.

42. The IC of claim 29, wherein the at least one MRAM bit cell comprises a plurality of MRAM bit cells in an MRAM array.

43. The IC of claim 42, wherein the MRAM array is disposed in a processor-based memory system of a central processing unit (CPU)-based system.

44. The IC of claim 42 integrated into a system-on-a-chip (SoC).

45. The IC of claim 29 integrated into a device selected from the group consisting of: a set top box; an entertainment unit; a navigation device; a communications device; a fixed location data unit; a mobile location data unit; a mobile phone; a cellular phone; a computer; a portable computer; a desktop computer; a personal digital assistant (PDA);
a monitor; a computer monitor; a television; a tuner; a radio; a satellite radio; a music player; a digital music player; a portable music player; a digital video player; a video player; a digital video disc (DVD) player; and a portable digital video player.

46. A method of fabricating a magnetic random access memory (MRAM) bit cell in an integrated circuit (IC), comprising:
forming an access transistor in a semiconductor layer, the access transistor comprising a gate, a source, and a drain;
forming a magnetic tunnel junction (MTJ) in a metal layer disposed above the semiconductor layer, the MTJ comprising a first end electrode and a second end electrode;
forming a drain-side connection column in at least one metal layer in the IC above the semiconductor layer coupling the drain of the access transistor to the first end electrode of the MTJ;
forming a source line in at least one metal layer above the semiconductor layer coupled to the source of the access transistor; and
forming a bit line in a plurality of stacked metal layers in the IC above the semiconductor layer coupled to the second end electrode of the MTJ.

47. The method of claim 46, wherein forming the bit line comprises forming the bit line in a plurality of stacked metal lines electrically coupled together in the plurality of stacked metal layers.

48. The method of claim 47, further comprising forming at least one elongated via disposed in the IC between at least two metal lines among the plurality of stacked metal lines of the bit line to couple the at least two metal lines among the plurality of stacked metal lines of the bit line together.

49. The method of claim 46, further comprising forming a plurality of the MRAM bit cells in the IC; and
wherein forming the bit line comprises forming a shared bit line in the plurality of stacked metal layers in the IC above the semiconductor layer, the shared bit line coupled to the second end electrode of the plurality of MRAM bit cells.
